(19) United States
(12) Patent Application Publication
(10) Pub. No.: US 2022/0260875 A1
(43) Pub. Date: Aug. 18, 2022

(54) LED Line Backlight Source Liquid Crystal Display Screen

(71) Applicant: FOSHAN NATIONSTAR OPTOELECTRONICS CO., LTD, Foshan City, Guangdong (CN)

(72) Inventors: Changqi WANG, Foshan City, Guangdong (CN); Kuai QIN, Foshan City, Guangdong (CN); Heng GUO, Foshan City, Guangdong (CN); Qiang ZHAO, Foshan City, Guangdong (CN); Kailiang FAN, Foshan City, Guangdong (CN)

(21) Appl. No.: 17/629,407

(22) PCT Filed: Jun. 29, 2020
(86) PCT No.: PCT/CN2020/098757

§ 371 Date: Jan. 24, 2022

(30) Foreign Application Priority Data
Jul. 24, 2019 (CN) 201910673225.6

(51) Int. Cl. G02F 1/13357; H01L 25/075; H01L 33/62; H01L 33/38

(52) U.S. Cl. CPC G02F 1/133603; H01L 33/382; H01L 33/62; H01L 25/0753

(57) ABSTRACT

Some embodiments of the present disclosure relate to the technical field of Light-Emitting Diodes (LEDs), for example, an LED line backlight source liquid crystal display screen, including liquid crystal glass and a light guide plate. The light guide plate is provided on one side of the liquid crystal glass, the outside of the end surface of a first end of the light guide plate and the outside of the end surface of a second end thereof are both provided with LED line backlight sources, the LED line backlight source includes an elongated circuit substrate, a side of the circuit substrate close to the light guide plate is provided with at least one row of light-emitting assemblies, and each row of the light-emitting assemblies includes a plurality of red, green, and blue (RGB) light-emitting units arranged at intervals along the length direction of the circuit substrate.

### CROSS-REFERENCE TO RELATED APPLICATION

The present disclosure claims priority to Chinese patent application No. 201910673225.6, filed to the China National Intellectual Property Administration on Jul. 24, 2019, the disclosure of which is hereby incorporated by reference in its entirety.

### TECHNICAL FIELD

The present disclosure relates to a technical field of Light-Emitting Diodes (LEDs), for example, an LED line backlight source liquid crystal display screen.

### BACKGROUND

Backlight of a Liquid Crystal Display (LCD) in a related technology basically uses a phosphor white light LED (Light Emitting Diode) lamp bead to provide a backlight light source. With a development of a technology, it is found that the phosphor white light LED lamp bead has following disadvantages: 1. a color of the phosphor white light LED lamp bead is fixed and can not be adjusted; and 2. a color gamut of the phosphor white light LED lamp bead is not wide enough. Therefore, the backlight source of an LCD screen known to inventors can not meet the requirements of a small-size display screen for the color gamut and brightness of the LCD screen.

### SUMMARY

Some embodiments of the present disclosure provide an LED line backlight source liquid crystal display, as to avoid the above situation.

Some embodiments of the present disclosure provide an LED line backlight source liquid crystal display screen, including liquid crystal glass and a light guide plate, the light guide plate is disposed on a side of the liquid crystal glass, and the light guide plate has a first end and a second end that are arranged oppositely, the first end and the second end are both extended to an outside of the liquid crystal glass, an outside of an end surface of the first end and an outside of an end surface of the second end are both provided with an LED line backlight source, and the LED line backlight source includes an circuit substrate which is of elongated shape, a side of the circuit substrate close to the light guide plate is provided with at least one row of light-emitting assemblies, and each row of the light-emitting assemblies includes a plurality of red, green, and blue (RGB) light-emitting units arranged at intervals along a length direction of the circuit substrate.

### BRIEF DESCRIPTION OF THE DRAWINGS

FIG. 1 illustrates a structure schematic diagram of an LED line backlight source liquid crystal display screen according to an embodiment of the present disclosure.

FIG. 2 illustrates an exploded schematic diagram of the LED line backlight source liquid crystal display screen according to an embodiment of the present disclosure.

FIG. 3 illustrates a schematic top view of an LED line backlight source according to an embodiment of the present disclosure.

FIG. 4 illustrates a schematic partial cross-sectional view of the LED line backlight source according to an embodiment of the present disclosure (encapsulation glue is not shown).

FIG. 5 illustrates a schematic partial cross-sectional view of the LED line backlight source according to an embodiment of the present disclosure.

FIG. 6 illustrates a schematic partial cross-sectional view of the LED line backlight source according to another embodiment of the present disclosure.

FIG. 7 illustrates a schematic top view of the LED line backlight source according to another embodiment of the present disclosure.

FIG. 8 illustrates a schematic partial cross-sectional view of the LED line backlight source according to another embodiment of the present disclosure (encapsulation glue is not shown).

FIG. 9 illustrates a schematic partial cross-sectional view of the LED line backlight source according to another embodiment of the present disclosure.

FIG. 10 illustrates a schematic partial cross-sectional view of the LED line backlight source according to another embodiment of the present disclosure.

FIG. 11 illustrates a schematic partial cross-sectional view of the LED line backlight source according to another embodiment of the present disclosure.

FIG. 12 illustrates an enlarged schematic diagram of A in FIG. 11.

FIG. 13 illustrates a schematic partial cross-sectional view of the LED line backlight source according to another embodiment of the present disclosure.

FIG. 14 illustrates an enlarged schematic diagram of B in FIG. 13.

FIG. 15 illustrates a circuit schematic diagram of the LED line backlight source according to an embodiment of the present disclosure.

In the drawings:

1. liquid crystal glass; 2. light guide plate; 21. first end; 22. second end; 23. first light guide portion; 24. second light guide portion; 25. third light guide portion; 3. LED line backlight source; 31. circuit substrate; 311. chip mounting layer; 3111. accommodating groove; 3112. separating plate; 31121. side surface; 3113. chamber; 3114. step; 3115. overflow glue groove; 312. circuit layer; 32. RGB light-emitting unit; 321. first chip; 322. second chip; 323. third chip; 324. common electrode; 325. first control electrode; 326. second control electrode; 327. third control electrode; and 33. encapsulation glue.

### DETAILED DESCRIPTION OF THE EMBODIMENTS

In descriptions of embodiments of the present disclosure, unless otherwise clearly specified and limited, terms “connected”, “linked”, and “fixed” should be interpreted broadly, for example, it may be a fixed connection or a detachable connection, or integrated; it may be a mechanical connection, or an electrical connection; it may be directly connected, or indirectly connected through an intermediate medium, or it may be an internal communication of two members or an interaction relationship between the two members. For those of ordinary skill in the art, the specific meanings of the above terms in the embodiments of the present disclosure may be understood in specific situations.

In the embodiments of the present disclosure, unless otherwise clearly specified and limited, a first feature “above” or “below” a second feature may include direct contact between the first and second features, or include that the first and second features are not in direct contact but in contact through another feature between them. Moreover, the first feature “on”, “above” and “over” the second feature includes that the first feature is directly above and obliquely above the second feature, or it is merely indicated that the level of the first feature is higher than that of the second feature. The first feature “under”, “below” and “beneath” the second feature includes that the first feature is directly below and obliquely below the second feature, or it is merely indicated that the level of the first feature is smaller than that of the second feature.

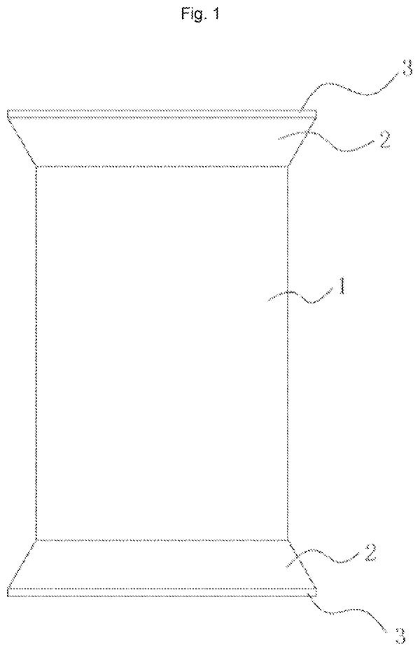

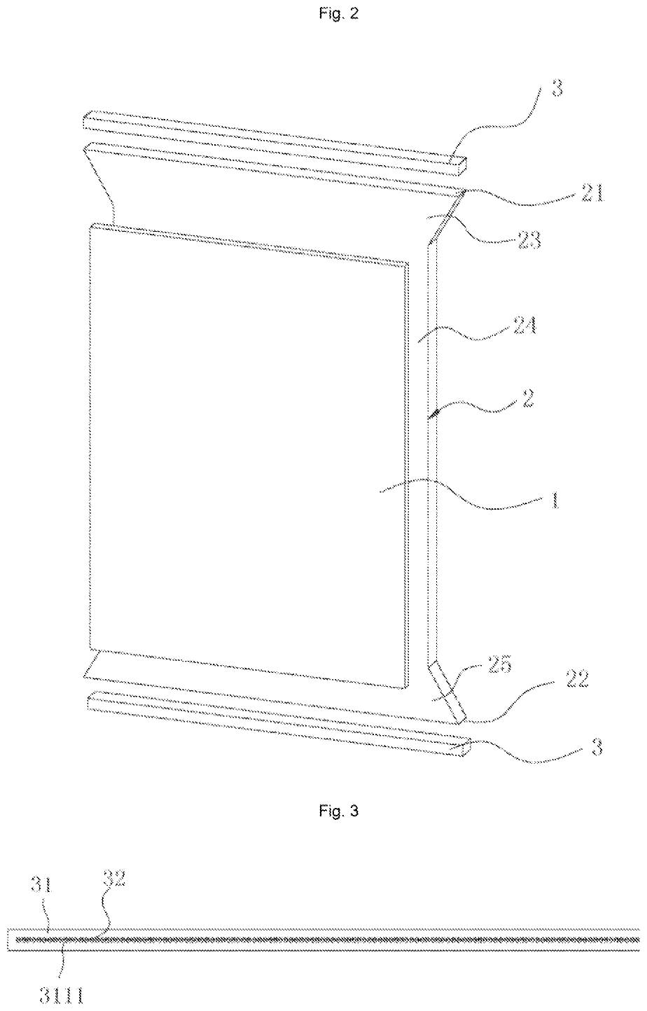

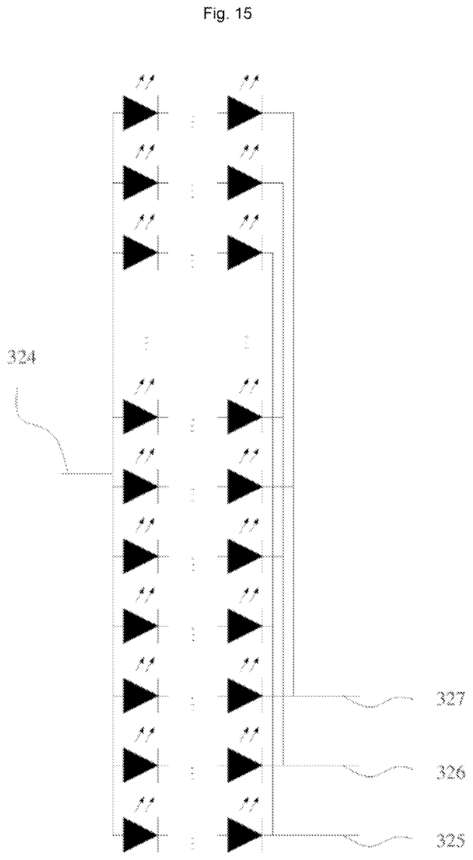

Referring to FIGS. 1 to 15, some embodiments of the present disclosure provides an LED line backlight source liquid crystal display screen, it is used for liquid crystal displays in positions such as a home appliance refrigerator, a washing machine, a microwave oven and an automobile window. The LED line backlight source liquid crystal display screen includes liquid crystal glass 1 and a light guide plate 2. The light guide plate 2 is disposed on a side of the liquid crystal glass 1 (a state of use is taken as an example, the light guide plate 2 is disposed on a back side of the liquid crystal glass 1), and the light guide plate 2 has a first end 21 and a second end 22 that are arranged oppositely, the first end 21 and the second end 22 are both extended to an outside of the liquid crystal glass 1, and an outside of an end surface of the first end 21 and an outside of an end surface of the second end 22 are both provided with an LED line backlight source 3. The LED line backlight source 3 includes a circuit substrate 31 which is of elongated shape, a length of the circuit substrate 31 is extended along a length or width direction of the liquid crystal glass 1, a side of the circuit substrate 31 close to the light guide plate 2 is provided with at least one row of light-emitting assemblies, and each row of the light-emitting assemblies includes a plurality of Red Green Blue (RGB) light-emitting units 32 arranged at intervals along the length direction of the circuit substrate 31. The RGB light-emitting unit 32 uses LED to achieve light emission. The liquid crystal glass 1, the light guide plate 2 and the LED line backlight source 3 constitute a transparent liquid crystal display screen structure, the LED line backlight source 3 provides a display light source on a side, the light guide plate 2 guides light, the liquid crystal glass 1 serves as a display part for display, and the plurality of the RGB light-emitting units 32 are linearly arranged on one side, close to the light guide plate 2, of the circuit substrate 31. Three-color LED chips of the RGB light-emitting units 32 are arranged in high density, and at the same time, in some embodiments, the three-color LED chips of the RGB light-emitting units 32 are independently controlled. The LED line backlight source 3 is adjusted according to the needs, and then a small size, short distance, high brightness, high color gamut and transparent display of the transparent liquid crystal display screen is achieved.

In some embodiments, the light guide plate 2 includes a first light guide portion 23, a second light guide portion 24 and a third light guide portion 25 that are sequentially connected, herein a size of the second light guide portion 24 is matched with a size of the liquid crystal glass 1, the first light guide portion 23 and the third light guide portion 25 are both located outside the liquid crystal glass 1. A width of one end, away from the liquid crystal glass 1, of the first light guide portion 23 is greater than a width of one end, connected to the second light guide portion 24, of the first light guide portion 23. A width of one end, away from the liquid crystal glass 1, of the third light guide portion 25 is greater than a width of one end, connected with the second light guide portion 24, of the third light guide portion 25. One end, away from the liquid crystal glass 1, of the first light guide portion 23 is the above first end 21. One end, away from the liquid crystal glass 1, of the third light guide portion 25 is the above second end 22. Exemplarily, widths of the first light guide portion 23 and the third light guide portion 25 are gradually increased from a contact point with the second light guide portion 24 toward a direction away from the second light guide portion 24. Exemplarily, the first light guide portion 23 and the third light guide portion 25 are a trapezoidal structure. A length of the LED line backlight source 3 is matched with lengths of end portions of the adjacent first light guide portion 23 and third light guide portion 25. Through a design of gradually increasing the widths of the first light guide portion 23 and the third light guide portion 25, a light on the most edge is condensed, and there is enough light on an edge portion of the display screen, so that the brightness of the edge and middle portions of the display screen is more uniform, to avoid that it is bright in a middle and dark on edges.

In some embodiments, the light guide plate 2 is transparent glass or transparent plastic with a light transmittance greater than or equal to 90%. Exemplarily, the transparent glass is colorless transparent common glass, colorless transparent tempered glass, colored transparent common glass, colored transparent tempered glass, or other special glass.

In some embodiments, the liquid crystal glass 1 is Thin Film Transistor (TFT) liquid crystal glass. Exemplarily, the liquid crystal glass 1 is common liquid crystal glass or high-transparent liquid crystal glass.

In some embodiment, the circuit substrate 31 is provided with at least two rows of light-emitting assemblies, and rows of the at least two rows of the light-emitting assemblies are arranged at intervals along the width direction of the circuit substrate 31. A plurality of rows of the light-emitting assemblies can enhance a display brightness of the LED line backlight source liquid crystal display screen.

In some embodiments, referring to FIGS. 3 to 6, the circuit substrate 31 includes at least three layers, namely a chip mounting layer 311, a circuit layer 312, and a member mounting layer (unshown in the figure). The chip mounting layer 311, the circuit layer 312 and the member mounting layer are sequentially arranged, the chip mounting layer 311 is provided with an accommodating groove 3111 penetrating along a thickness direction of the chip mounting layer 311, the RGB light-emitting units 32 are arranged in the accommodating groove 3111, the circuit layer 312 is provided with a bonding pad for fixing the RGB light-emitting units 32, and a member on the member mounting layer is electrically connected to the RGB light-emitting unit 32 through a circuit in the circuit layer 312. By arranging the circuit substrate 31 as a multilayer structure, it is easy to manufacture, and a yield rate of product molding is improved.

In some embodiments, a member on the member mounting layer is mainly an Integrated Circuit (IC) chip, a resistor, a capacitor and the like or a connector pin welding layer.

In some embodiments, the chip mounting layer 311 is combined with the circuit layer 312 in a lamination manner. The lamination manner achieves the separate manufacture of the circuit layer 312 and the chip mounting layer 311, and it is convenient for forming the accommodating groove 3111 and mounting the RGB light-emitting units 32.

In other embodiments, the chip mounting layer 311 is also combined with the circuit layer 312 in a 3D printing manner. This manner makes a combination tightness degree of the chip mounting layer 311 and the circuit layer 312 higher, and it does not need to prepare a laminated plate in advance. The chip mounting layer 311 is directly formed on the surface of the circuit layer 312, the operation is convenient, and the precision is high.

In some embodiments, a groove wall of the accommodating groove 3111 on the chip mounting layer 311 is white, so that the light reflection effect is better.

In some embodiments, a depth of the accommodating groove 3111 is H, and a height of the RGB light-emitting unit 32 is h, herein 1.5h≤H≤4h. This design makes the accommodating groove 3111 have an enough depth to accommodate chips of the RGB light-emitting units 32, and provide a space for encapsulation glue 33. At the same time, a thickness of the entire LED line backlight source 3 is reduced as much as possible, so that the LED line backlight source liquid crystal display screen achieves a narrow frame design.

In some embodiment, referring to FIGS. 3 to 6, a plurality of separating plates 3112 is arranged in the accommodating groove 3111, and the plurality of the separating plates 3112 divides the accommodating groove 3111 into a plurality of chambers 3113 arranged along the length direction of the circuit substrate 31, and each of the plurality of chambers 3113 is internally provided with at least one RGB light-emitting unit 32. By arranging the separating plates 3112, the RGB light-emitting units 32 in the adjacent chambers 3113 is effectively prevented from cross-light, and a light mixing effect of the adjacent RGB light-emitting units 32 is improved. In other embodiments, referring to FIGS. 7 to 10, the separating plates 3112 in the accommodating groove 3111 is also eliminated, namely all the RGB light-emitting units 32 are placed in a same accommodating groove 3111.

In some embodiments, each chamber 3113 is internally provided with one RGB light-emitting unit 32. All the RGB light-emitting units 32 of the LED line backlight source 3 are separated by the separating plates 3112, namely each RGB light-emitting unit 32 is placed in one independent chamber 3113, so a better light mixing effect and anti-cross-light effect is achieved.

In some embodiment, the chip mounting layer 311 has a first side surface attached to the circuit layer 312 and a second side surface arranged opposite to the first side surface, and an upper end surface of the separating plate 3112 is flush with the second side surface. In other embodiments, the upper end surface of the separating plate 3112 is lower than the second side surface.

In some embodiments, the accommodating groove 3111 is internally provided with the encapsulation glue 33, and the encapsulation glue 33 encapsulates the RGB light-emitting units 32 in the accommodating groove 3111 by modes of dispensing, mold-pressing or injection-molding.

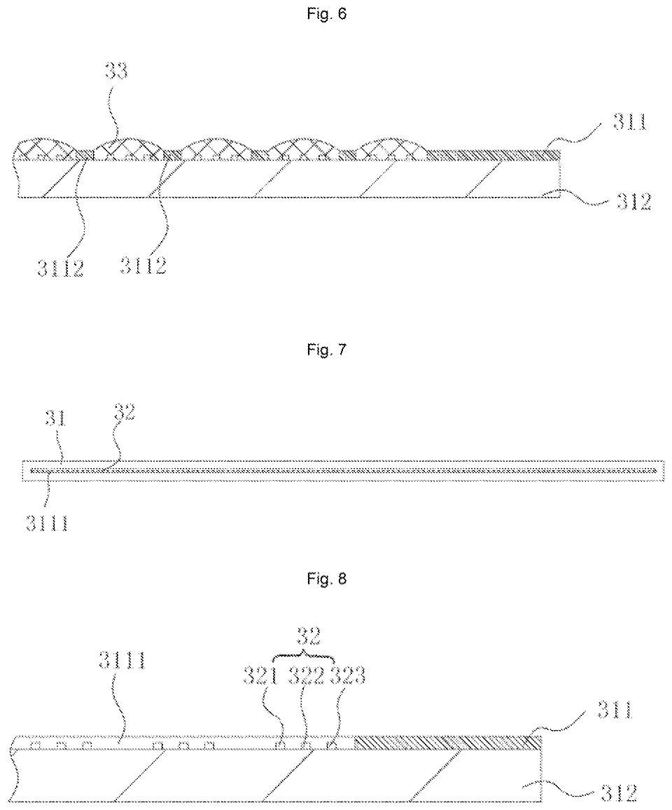

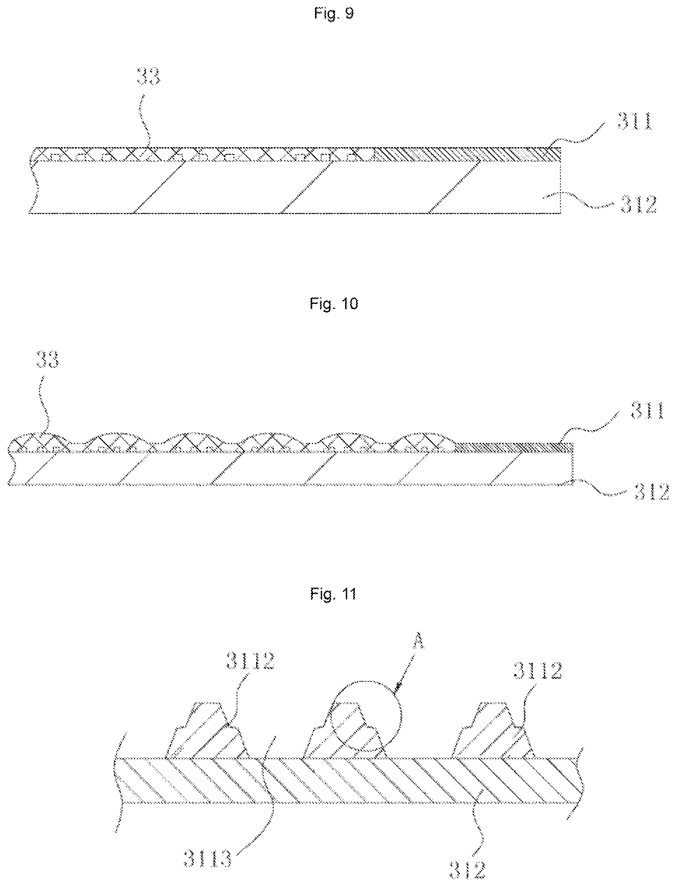

In this embodiment, an upper surface of the formed encapsulation glue 33 after being formed is a flat surface or a convex arc surface. Referring to FIGS. 5 and 9, it shows a structure in which the upper surface of the formed encapsulation glue 33 is the flat surface, and referring to FIGS. 6 and 10, it shows a structure in which the upper surface of the formed encapsulation glue 33 is the convex arc surface.

The encapsulation glue 33 is internally mixed with a homogenizing material, and the homogenizing material is cobalt dioxide or organopolysiloxane.

The separating plate 3112 is also provided with an anti-overflow glue structure, referring to FIGS. 11 to 14, the anti-overflow glue structure is concave-formed from a surface of the separating plate 3112 toward the interior of the separating plate 3112.

In an embodiment, the anti-overflow glue structure includes a concave structure arranged on at least one side surface of the separating plate 3112.

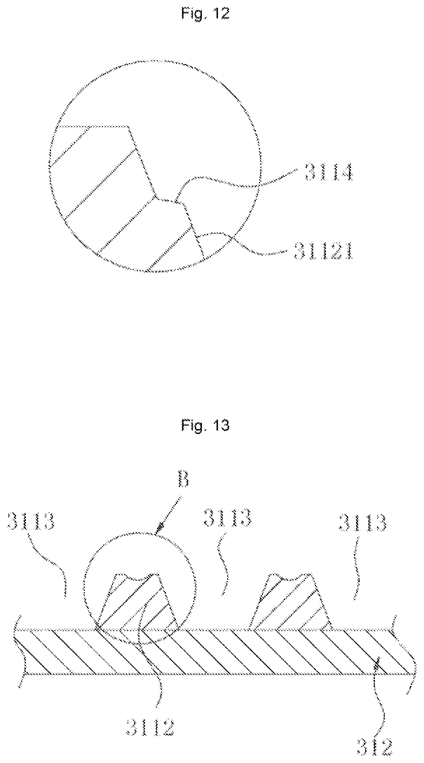

Referring to FIGS. 11 and 12, the concave structure is formed by a step 3114. Exemplarily, at least one side surface of the separating plate 3112 is provided with the step 3114, and the step 3114 is spaced from the upper end surface of the separating plate 3112. By arranging the step 3114, while the RGB light-emitting unit 32 is encapsulated, the encapsulation glue 33 is buffered by the step 3114, a speed of the encapsulation glue 33 is slowed down, and the encapsulation glue 33 is effectively prevented from overflowing the separating plate 3112. An included angle between the step 3114 and the horizontal plane is 0-30 degrees.

The separating plate 3112 has two side surfaces 31121 that are arranged oppositely, and two side surfaces 31121 are both provided with the steps 3114. This design prevents the encapsulation glue 33 on both sides of the separating plate 3112 from overflowing, and reduces the mutual influence.

In some embodiment, the side surface 31121 is provided with a step 3114, or the side surface 31121 is provided with at least two steps 3114, and a width of the step 3114 is gradually reduced from a bottom of the chamber 3113 to a chamber opening. This design is not only strengthen the buffering of the encapsulation glue 33 and guarantee that the encapsulation glue 33 does not overflow at all, but also reduces the manufacturing difficulty.

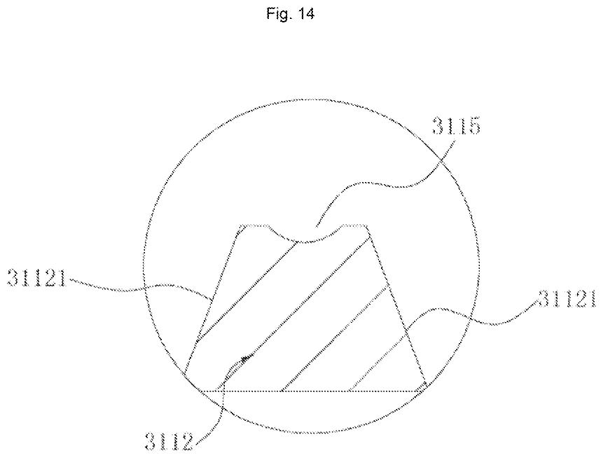

The anti-overflow glue structure is not limited to the concave structure arranged on the side surface 31121 of the separating plate 3112, but also is an overflow glue groove 3115 arranged on the upper end surface of the separating plate 3112. Referring to FIGS. 13 and 14, the anti-overflow glue structure is the overflow glue groove 3115 concave-arranged on the upper end surface of the separating plate 3112. By arranging the overflow glue groove 3115, the overflowed encapsulation glue 33 is buffered, and the encapsulation glue 33 is prevented from overflowing into areas, in which the RGB light-emitting units 32 are mounted, on both sides of the separating plate 3112.

In some embodiments, the overflow glue groove 3115 is an arc-shaped groove. The arc-shaped groove slows down the flow rate of the encapsulation glue 33, and prevents the encapsulation glue 33 from overflowing due to the excessive speed during glue injection.

In addition, in some embodiments, both the step 3114 and the overflow glue groove 3115 is disposed on the separating plate 3112, as to improve the anti-overflow glue effect.

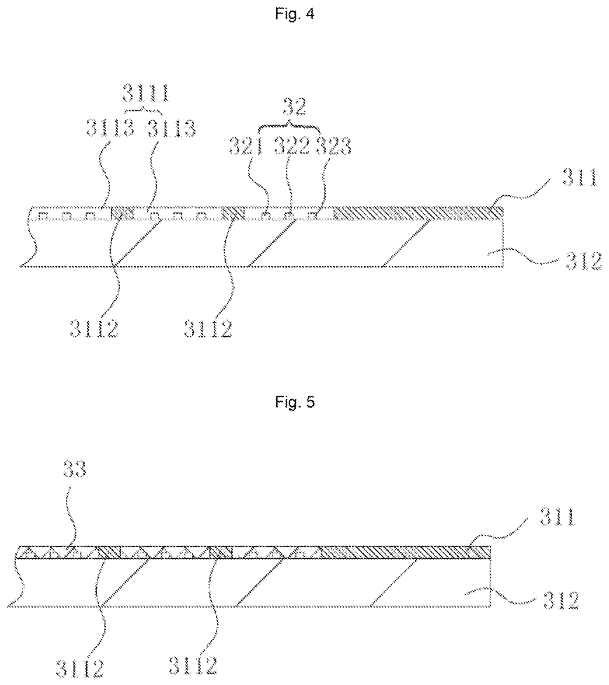

In some embodiments, referring to FIGS. 4, 8 and 15, each RGB light-emitting unit 32 includes a first chip 321, a second chip 322 and a third chip 323 that are arranged at intervals. Each of the first chip 321, the second chip 322 and the third chip 323 is provided with a first electrode and a second electrode. The first electrodes of all the first chips 321, the second chips 322 and the third chips 323 of the plurality of the RGB light-emitting units 32 are electrically connected to form a common electrode 324. The second electrodes of all the first chips 321 of the plurality of RGB light-emitting units 32 are electrically connected to form a first control electrode 325. The second electrodes of all the second chips 322 of the plurality of the RGB light-emitting units 32 are electrically connected to form a second control electrode 326. The second electrodes of all the third chips 323 of the plurality of the RGB light-emitting units 32 are electrically connected to form a third control electrode 327. This design reduces the use of a bonding pad, and also achieves the simultaneous control of the chips with the same color, and the independent control of the chips with the different colors, the requirements of color adjustment are satisfied, the control difficulty of the color adjustment is low, and the cost is low.

In other embodiments, the chips with the same color are divided into a plurality of groups, the chips with the same color in each group are connected in series, and the plurality of the groups is connected in parallel. For example, all the first chips 321 of the plurality of the RGB light-emitting units 32 are divided into M₁ groups, each group of the M₁ groups includes N₁ first chips 321, the N₁ first chips 321 in the each group are connected in series and the second electrode of the last first chip 321 in this group forms the first control electrode 325, and M₁ first control electrodes 325 are electrically connected. All the second chips 322 of the plurality of the RGB light-emitting units 32 are divided into M₂ groups, each group of the M₂ groups includes N₂ second chips 322, the N₂ second chips 322 in each group are connected in series and the second electrode of the last second chip in this group forms the second control electrode 326, and the M₂ second control electrodes 326 are electrically connected. All the third chips 323 of the plurality of the RGB light-emitting units 32 are divided into M₃ groups, each group of the M₃ groups includes N₃ third chips 323, the N₃ third chips 323 in each group are connected in series and the second electrode of the last third chip 323 in this group forms the third control electrode 327, and the M₃ third control electrodes 327 are electrically connected. The first electrode of the first chip 321 in each group of the serially connected first chips 321, the first electrode of the first second chip 322 in each group of the serially connected second chips 322, and the first electrode of the first third chip 323 in each group of the serially connected third chips 323 are electrically connected to form the common electrode 324.

Herein, the numbers of M₁, M₂, and M₃ are set to be the same or different. Similarly, the numbers of N₁, N₂, and N₃ are set to be the same or different.

In this embodiment, the first chips 321, the second chips 322 and the third chips 323 are arranged at intervals along the length direction of the circuit substrate 31.

In descriptions of the description, the descriptions with reference to terms “an embodiment”, “example”, and the like means that the specific features, structures, materials or characteristics described in combination with the embodiment or example is included in at least one embodiment or example of the present disclosure. In the description, the schematic representations of the above terms do not necessarily refer to the same embodiment or example. Moreover, the described specific features, structures, materials or characteristics may be combined in an appropriate manner in at least one embodiment or example.

What is claimed is:

1. A Light-Emitting Diode (LED) line backlight source liquid crystal display screen, comprising liquid crystal glass and a light guide plate, wherein the light guide plate is disposed on a side of the liquid crystal glass, the light guide plate has a first end and a second end that are arranged oppositely, the first end and the second end are both extended to an outside of the liquid crystal glass, an outside of an end surface of the first end and an outside of an end surface of the second end are both provided with an LED line backlight source, the LED line backlight source comprises an circuit substrate which is of elongated shape, a side of the circuit substrate close to the light guide plate is provided with at least one row of light-emitting assemblies, and each row of the light-emitting assemblies comprises a plurality of Red Green Blue (RGB) light-emitting units arranged at intervals along a length direction of the circuit substrate.

2. The display screen as claimed in claim 1, wherein the circuit substrate is provided with at least two rows of light-emitting assemblies, and the at least two rows of the light-emitting assemblies are arranged at intervals along a width direction of the circuit substrate.

3. The display screen as claimed in claim 1, wherein the circuit substrate comprises at least three layers, the at least three layers comprises a chip mounting layer, a circuit layer, and a member mounting layer, wherein the chip mounting layer, the circuit layer and the member mounting layer are sequentially arranged, the chip mounting layer is provided with an accommodating groove penetrating along a thickness direction of the chip mounting layer, the RGB light-emitting units are arranged in the accommodating groove, the circuit layer is provided with a bonding pad for fixing the RGB light-emitting units, and a member on the member mounting layer is electrically connected to the RGB light-emitting unit through a circuit in the circuit layer.

4. The display screen as claimed in claim 3, wherein the chip mounting layer is combined with the circuit layer in a lamination manner or a 3D printing manner.

5. The display screen as claimed in claim 4, wherein a depth of the accommodating groove is H, and a height of the RGB light-emitting unit is h, wherein 1.5h≤H≤4h.

6. The display screen as claimed in claim 3, wherein a plurality of separating plates is disposed in the accommodating groove, and the plurality of the separating plates divides the accommodating groove into a plurality of chambers arranged along the length direction of the circuit substrate, and each of the plurality of chambers is internally provided with at least one RGB light-emitting unit.

7. The display screen as claimed in claim 1, wherein the light guide plate comprises a first light guide portion, a second light guide portion and a third light guide portion which are sequentially connected, wherein a size of the second light guide portion is matched with a size of the liquid crystal glass, the first light guide portion and the third light guide portion are both located outside the liquid crystal glass, a width of an end, away from the liquid crystal glass, of the first light guide portion is greater than a width of an end, connected with the second light guide portion, of the first light guide portion, a width of an end, away from the liquid crystal glass, of the third light guide portion is greater than a width of an end, connected with the second light guide portion, of the third light guide portion, an end, away from the liquid crystal glass, of the first light guide portion is the first end, and an end, away from the liquid crystal glass, of the third light guide portion is the second end.

8. The display screen as claimed in claim 3, wherein the accommodating groove is internally provided with encapsulation glue, and the encapsulation glue encapsulates the RGB light-emitting units in the accommodating groove by manners of dispensing, mold-pressing or injection-molding.

9. The display screen as claimed in claim 8, wherein an upper surface of the encapsulation glue after being formed is a flat surface or a convex arc surface.

10. The display screen as claimed in claim 8, wherein the encapsulation glue is internally mixed with a homogenizing material, and the homogenizing material is cobalt dioxide or organopolysiloxane.

11. The display screen as claimed in claim 1, wherein each of the RGB light-emitting units comprises a first chip, a second chip and a third chip that are disposed at intervals, each of the first chip, the second chip and the third chip is provided with a first electrode and a second electrode, first electrodes of all the first chips, the second chips and the third chips of the plurality of the RGB light-emitting units are electrically connected to form a common electrode;
second electrodes of all the first chips of the plurality of the RGB light-emitting units are electrically connected to form a first control electrode, second electrodes of all the second chips of the plurality of the RGB light-emitting units are electrically connected to form a second control electrode, second electrodes of all the third chips of the plurality of the RGB light-emitting units are electrically connected to form a third control electrode; or,
all the first chips of the plurality of the RGB light-emitting units are divided into M1 groups, each group of the M1 groups comprises N1 first chips, the N1 first chips in the each group are connected in series to form the first control, M1 first control electrodes are electrically connected, all the second chips of the plurality of the RGB light-emitting units are divided into M2 groups, each group of the M2 groups contains N2 second chips, the N2 second chips in each group are connected in series to form the second control electrode, M2 second control electrodes are electrically connected, all the third chips of the plurality of the RGB light-emitting units are divided into M3 groups, each group of the M3 groups contains N3 third chips, N3 third chips in each group are connected in series to form the third control electrode, and the M3 third control electrodes are electrically connected.

12. The display screen as claimed in claim 1, wherein the light guide plate is a transparent glass or transparent plastic with a light transmittance greater than or equal to 90%.
